(19) United States
(12) Patent Application Publication
(10) Pub. No.: US 2023/0398654 A1
(43) Pub. Date: Dec. 14, 2023

(54) WORKPIECE GRINDING METHOD

(71) Applicant: DISCO CORPORATION, Tokyo (JP)

(72) Inventors: Aki TAKAHASHI, Tokyo (JP); Takuya MIHARA, Tkyo (JP)

(21) Appl. No.: 18/325,337

(22) Filed: May 30, 2023

(30) Foreign Application Priority Data
Jun. 10, 2022 (JP) 2022-094055

(51) Int. Cl. B24B 7/22; H01L 21/683; H01L 21/304

(52) U.S. Cl. CPC B24B 7/228; H01L 21/6836; H01L 21/304; H01L 2221/68327

(57) ABSTRACT

Provided is a workpiece grinding method that is applied when a circular plate-shaped workpiece which has a first surface and a second surface on an opposite side of the first surface is to be ground. The workpiece grinding method includes a first grinding step of grinding the workpiece to form a circular plate-shaped first thin plate portion and an annular first thick plate portion that surrounds the first thin plate portion and that has an inner side surface at least part of which is inclined with respect to the second surface, and a second grinding step of grinding the workpiece to form a circular plate-shaped second thin plate portion that is larger in diameter but thinner than the first thin plate portion and an annular second thick plate portion that surrounds the second thin plate portion.

### BACKGROUND OF THE INVENTION

### Field of the Invention

The present invention relates to a workpiece grinding method that is applied when a circular plate-shaped workpiece as exemplified by a wafer is to be ground.

### Description of the Related Art

In order to realize small and light device chips, there are increasing situations for performing processing to thin a wafer with a face side on which such devices as integrated circuits (ICs) are provided. For example, the face side of the wafer is held on a chuck table, and the chuck table and a grinding wheel to which grindstones including abrasive grains are fixed are rotated. Then, the grindstones are pressed against a reverse side of the wafer while liquid such as pure water is supplied, so that the wafer is ground and thinned.

When the wafer is in whole thinned by the above-mentioned method, rigidness of the wafer significantly declines, creating difficulty in handling the wafer in subsequent steps. As such, there has been proposed a technique of maintaining high rigidness of a ground wafer by using a grinding wheel with a smaller diameter than the wafer to grind an area on a central side (inner side) of the wafer on which devices are formed and leave an area on an outer edge side (outer side) unground (see, for example, Japanese Patent Laid-open No. 2007-19461).

In this technique, first, the area on the central side of the wafer is coarsely ground by a first grinding wheel to which grindstones including relatively large abrasive grains are fixed, so that a circular plate-shaped thin plate portion and an annular thick plate portion that surrounds the thin plate portion are formed in the wafer. As described, using a grinding wheel to which grindstones including large abrasive grains are fixed requires less time for grinding the wafer than using a grinding wheel to which grindstones including small abrasive grains are fixed.

Meanwhile, coarsely grinding the wafer by a grinding wheel to which grindstones including large abrasive grains are fixed leads to formation of a damaged layer including scratches or distortions attributable to the grindstones on the ground side of the wafer, possibly resulting in insufficient mechanical strength (die strength or the like) of the thin plate portion. As such, after the wafer has been coarsely ground, the thin plate portion is further ground by a grinding wheel to which grindstones including relatively small abrasive grains are fixed, so that the damaged layer is removed.

### SUMMARY OF THE INVENTION

Incidentally, when the grinding wheel comes into contact with a perpendicular inner side surface of the thick plate portion at the time of further grinding the thin plate portion and removing the damaged layer, the thick plate portion sometimes chips. Thus, at the time of removing the damaged layer, only the area on the central side of the thin plate portion has been ground so that the grinding wheel would not come into contact with the thick plate portion. However, this method leaves the damaged layer in the area on the outer edge side of the thin plate portion (an area near a boundary between the thin plate portion and the thick plate portion), making it difficult to use this area for products.

It is accordingly an object of the present invention to provide a workpiece grinding method that is capable of sufficiently reserving an effective area that can be used for products, without requiring a considerably long period of time compared to the grinding method used in the related art, at the time of grinding a circular plate-shaped workpiece and forming a thin plate portion and a thick plate portion therein.

In accordance with an aspect of the present invention, there is provided a workpiece grinding method that is applied when a circular plate-shaped workpiece having a first surface and a second surface on an opposite side of the first surface is to be ground, the workpiece grinding method including a first grinding step of grinding the workpiece by moving the workpiece and a first grinding wheel relative to each other while rotating them, the first grinding wheel including a plurality of first grindstones that each include abrasive grains and are arrayed in an annular area with a first diameter smaller than a diameter of the workpiece, and causing the first grindstones to come into contact with the workpiece from the second surface side, to thereby form in the workpiece a circular plate-shaped first thin plate portion and an annular first thick plate portion that surrounds the first thin plate portion and that has an inner side surface at least part of which is inclined with respect to the second surface, and a second grinding step of, after the first grinding step, grinding the workpiece by moving the workpiece and a second grinding wheel relative to each other while rotating them, the second grinding wheel including a plurality of second grindstones that each include abrasive grains smaller than those of the first grindstones and are arrayed in an annular area with a second diameter smaller than the diameter of the workpiece, and causing the second grindstones to come into contact with one of the first thin plate portion or the part of the side surface of the first thick plate portion from the second surface side and then with the other of the first thin plate portion or the part of the side surface of the first thick plate portion, in such a manner that the part of the side surface of the first thick plate portion is partially removed, to thereby form in the workpiece a circular plate-shaped second thin plate portion that is larger in diameter but thinner than the first thin plate portion and an annular second thick plate portion that surrounds the second thin plate portion.

Preferably, in the first grinding step, the first grinding wheel and the workpiece are moved relative to each other in a direction inclined with respect to the second surface, in such a manner that a center of rotation of the first grinding wheel approaches a center of rotation of the workpiece.

Moreover, preferably, in the first grinding step, after the first grinding wheel and the workpiece are moved relative to each other in a direction that intersects the second surface, in such a manner that a center of rotation of the first grinding wheel does not approach a center of rotation of the workpiece, the first grinding wheel and the workpiece are moved relative to each other in a direction inclined with respect to the second surface, in such a manner that the center of rotation of the first grinding wheel approaches the center of rotation of the workpiece.

Preferably, in the second grinding step, the second grinding wheel and the workpiece are moved relative to each other in a direction inclined with respect to the second surface, in such a manner that a center of rotation of the second grinding wheel is distanced from a center of rotation of the workpiece.

Moreover, in the second grinding step, after at least the first thin plate portion is ground by moving the second grinding wheel and the workpiece relative to each other in a direction that intersects the second surface, in such a manner that a center of rotation of the second grinding wheel is not distanced from a center of rotation of the workpiece, at least the part of the side surface of the first thick plate portion may partially be removed by moving the second grinding wheel and the workpiece relative to each other in a direction along the second surface in such a manner that the center of rotation of the second grinding wheel is distanced from the center of rotation of the workpiece.

Further, in the second grinding step, after at least the part of the side surface of the first thick plate portion is partially removed by moving the second grinding wheel and the workpiece relative to each other in a direction along the second surface, in such a manner that a center of rotation of the second grinding wheel is distanced from a center of rotation of the workpiece, at least the first thin plate portion may be ground by moving the second grinding wheel and the workpiece relative to each other in a direction that intersects the second surface, in such a manner that the center of rotation of the second grinding wheel is not distanced from the center of rotation of the workpiece.

In the workpiece grinding method according to the aspect of the present invention, first, the workpiece is ground by the first grinding wheel including the first grindstones, and the first thin plate portion and the annular first thick plate portion having the inner side surface at least part of which is inclined are formed. Then, the workpiece is ground by causing the second grindstones that include small abrasive grains compared to the first grindstones and are included in the second grinding wheel to come into contact with one of the first thin plate portion or part of the inclined side surface of the first thick plate portion and then with the other of the first thin plate portion or the part of the inclined side surface of the first thick plate portion, in such a manner that the part of the inclined side surface of the first thick plate portion is partially removed, so that the second thin plate portion and the second thick plate portion are formed.

Accordingly, the second thin plate portion in whole becomes an effective area free of damaged layers attributable to the first grindstones. Further, at this time, the first thick plate portion is ground in such a manner that part of the inclined side surface is partially removed, so that the first thick plate portion becomes less likely to chip, unlike in the case where the first thick plate portion is ground from the lateral side by the second grindstones being caused to come into contact with a perpendicular side surface.

Further, since the volume of the portion of the first thick plate portion that is removed by the second grinding wheel is sufficiently small, for example, the length of time required for grinding does not become considerably long compared to the length of time required in the grinding method in the related art in which the second grinding wheel grinds only the area on the central side of the first thin plate portion and not the first thick plate portion at all. Accordingly, the workpiece grinding method according to the aspect of the present invention sufficiently reserves an effective area that can be used for products, without requiring a considerably longer time than the grinding method in the related art.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a state in which a protective member is affixed to a circular plate-shaped workpiece;

FIG. 2 is a cross sectional view schematically illustrating a state in which the workpiece is held on a chuck table through the protective member;

FIG. 3 is a cross sectional view schematically illustrating a state in which grinding of the workpiece by a first grinding wheel is started;

FIG. 4 is a cross sectional view schematically illustrating a state in which grinding of the workpiece by the first grinding wheel is proceeding;

FIG. 5 is a cross sectional view schematically illustrating part of the workpiece that has been ground by the first grinding wheel;

FIG. 6 is a cross sectional view schematically illustrating a state in which grinding of the workpiece by a second grinding wheel is started;

FIG. 7 is a cross sectional view schematically illustrating a state in which grinding of the workpiece by the second grinding wheel is proceeding;

FIG. 8 is a cross sectional view schematically illustrating part of the workpiece that has been ground the second grinding wheel;

FIG. 9 is a cross sectional view schematically illustrating part of the workpiece that is being ground by the second grinding wheel in the workpiece grinding method according to a first modification of an embodiment of the present invention;

FIG. 10 is a cross sectional view schematically illustrating part of the workpiece that has been ground by the first grinding wheel in the workpiece grinding method according to a second modification of the embodiment; and

FIG. 11 is a cross sectional view schematically illustrating part of the workpiece that has been ground by the second grinding wheel in the workpiece grinding method according to the second modification.

### DETAILED DESCRIPTION OF THE PREFERRED EMBODIMENT

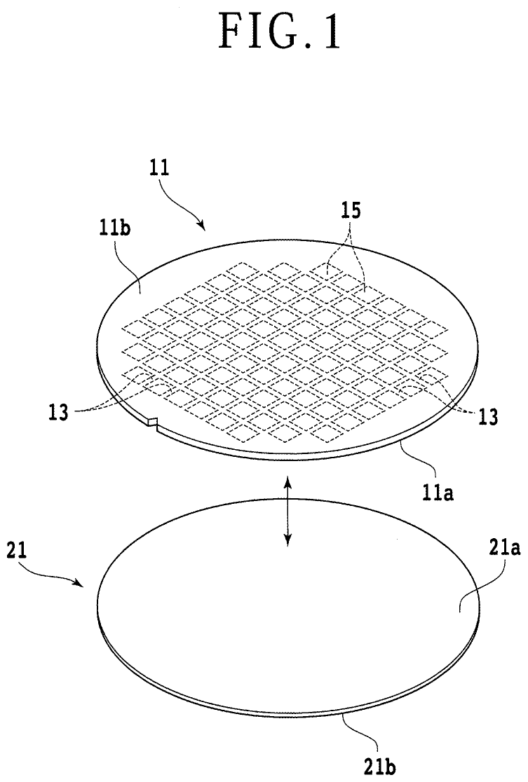

An embodiment of the present invention will be described below with reference to the attached drawings. In a workpiece grinding method according to the present embodiment, an area on a central side (inner side) of a circular plate-shaped workpiece that is to be ground is ground, so that a recessed shaped workpiece with that area thinned is obtained. Specifically, first, a protective member is affixed to the workpiece (affixing step). FIG. 1 is a perspective view schematically illustrating a state in which the protective member denoted by 21 is affixed to the circular plate-shaped workpiece denoted by 11.

As illustrated in FIG. 1, the workpiece 11 is, for example, a circular plate-shaped wafer configured from a semiconductor such as silicon (Si). Specifically, the workpiece 11 has a circular face side (first surface) 11a and a circular reverse side (second surface) 11b on an opposite side of the face side 11a. The face side 11a of the workpiece 11 is partitioned into a plurality of small areas by a plurality of streets (projected dicing lines) 13 in crisscross relation. In the small areas, devices 15 such as ICs are formed.

In the workpiece grinding method according to the present embodiment, a portion of the workpiece 11 that corresponds to an area (device area) in which the devices 15 are formed is ground from the reverse side 11b, and a remaining annular area (outer peripheral area) is not ground. That is, the workpiece 11 is processed from the reverse side 11b to have a recessed shape.

Note that, in the present embodiment, a circular plate-shaped wafer configured from a semiconductor such as silicon is used as the workpiece 11, but the material, shape, structure, size, and the like of the workpiece 11 are not limited to the forms described above. For example, substrates configured from such materials as other semiconductors, ceramic, resin, or metal can be used as the workpiece 11. Similarly, the type, number, shape, structure, size, arrangement, and the like of the devices 15 are not limited to the above-mentioned forms. The workpiece 11 may not have the devices 15 formed thereon.

The protective member 21 to be affixed to the workpiece 11 is typically a circular tape (film), resin substrate, wafer of the same or different kind with respect to the workpiece 11, or the like that has a diameter substantially equal to that of the workpiece 11. Specifically, the protective member 21 has a circular face side 21a and a circular reverse side 21b that is on an opposite side of the face side 21a. On the face side 21a of the protective member 21, for example, an adhesive layer demonstrating adhesive property with respect to the workpiece 11 is provided.

As depicted in FIG. 1, when the face side 21a of the protective member 21 is brought into close contact with the face side 11a of the workpiece 11, the protective member 21 is affixed to the face side 11a of the workpiece 11. As a result, impact caused to the face side 11a of the workpiece 11 at the time when the workpiece 11 is ground from the reverse side 11b is reduced by the protective member 21, and the devices 15 and the like formed on the workpiece 11 are protected. Yet, in a case where the devices 15 are not formed on the workpiece 11, for example, the protective member 21 is not necessarily required to be affixed to the workpiece 11.

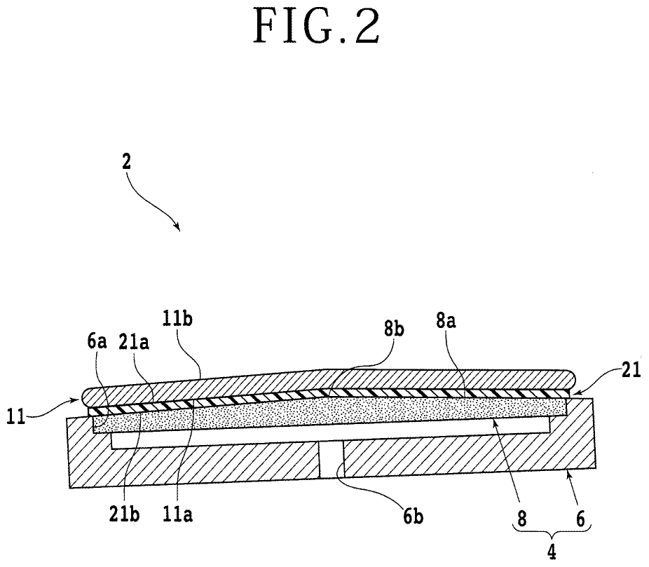

After the protective member 21 is affixed to the face side 11a of the workpiece 11, the workpiece 11 is held on a chuck table through the protective member 21 (holding step). FIG. 2 is a cross sectional view schematically illustrating a state in which the workpiece 11 is held on a chuck table 4 of a grinding apparatus 2 through the protective member 21. Note that, in the steps described below, the grinding apparatus 2 illustrated in FIG. 2 or the like is used.

The grinding apparatus 2 includes the chuck table 4 configured to be capable of holding the workpiece 11. The chuck table 4 includes, for example, a circular plate-shaped frame body 6 that is formed with use of ceramic or the like. On an upper surface side of the frame body 6, there is formed a recessed portion 6a which has a circular opening in its upper end. Fixed to the recessed portion 6a is a porous holding plate 8 formed in a circular plate shape with use of ceramic or the like.

An upper surface 8a of the holding plate 8 is, for example, configured in a shape corresponding to a conical surface and functions as a holding surface for holding the workpiece 11 or the like. Note that the difference in height (height difference) between a center 8b of the upper surface 8a of the holding plate 8, which corresponds to a vertex of a cone, and an outer peripheral edge of the upper surface 8a of the holding plate 8 is approximately 10 μm to 30 μm. In the present embodiment, the upper surface (holding surface) 8a of the holding plate 8 comes into contact with the reverse side 21b of the protective member 21.

A lower surface side of the holding plate 8 is connected to a suction source (not illustrated) such as an ejector through a suction channel 6b provided inside the frame body 6, a valve (not illustrated) disposed outside of the frame body 6, and the like. Accordingly, when the valve is opened and a negative pressure generated at the suction source is caused to act in a state in which the reverse side 21b of the protective member 21 is in contact with the upper surface 8a of the holding plate 8, the reverse side 21b of the protective member 21 is sucked by the chuck table 4.

That is, the workpiece 11 is held on the chuck table 4 through the protective member 21 in such a manner that the reverse side 11b is exposed upward. In a case where the protective member 21 is not affixed to the face side 11a of the workpiece 11, the valve may be opened, and the negative pressure generated at the suction source may be caused to act, with the upper surface 8a of the holding plate 8 having direct contact with the face side 11a of the workpiece 11.

To a lower portion of the frame body 6, a rotary drive source (not illustrated), such as a motor, is coupled. By power generated by the rotary drive source, the chuck table 4 rotates about an axis along or slightly inclined with respect to a vertical direction, such that the center 8b of the upper surface 8a becomes the center of rotation. Further, the frame body 6 is supported by a chuck table moving mechanism (not illustrated) with a ball screw for linear movement or a turntable for rotational movement, for example, and the chuck table 4 moves in a horizontal direction by power generated by the chuck table moving mechanism.

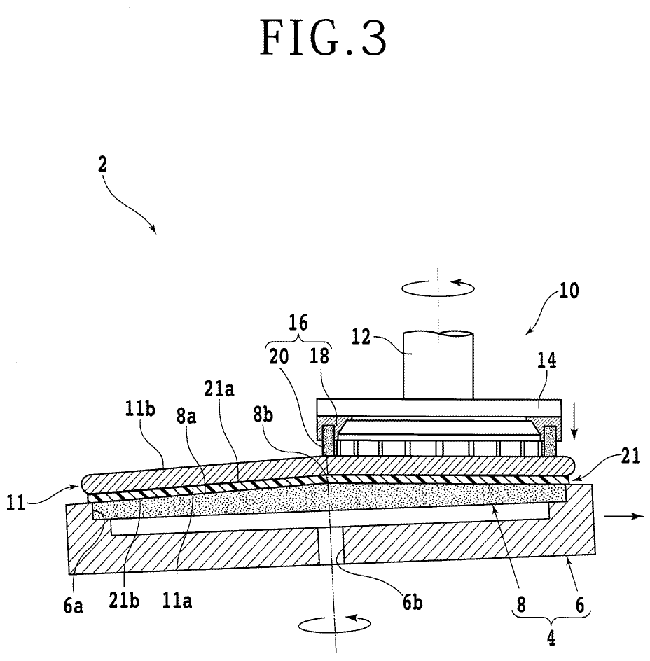

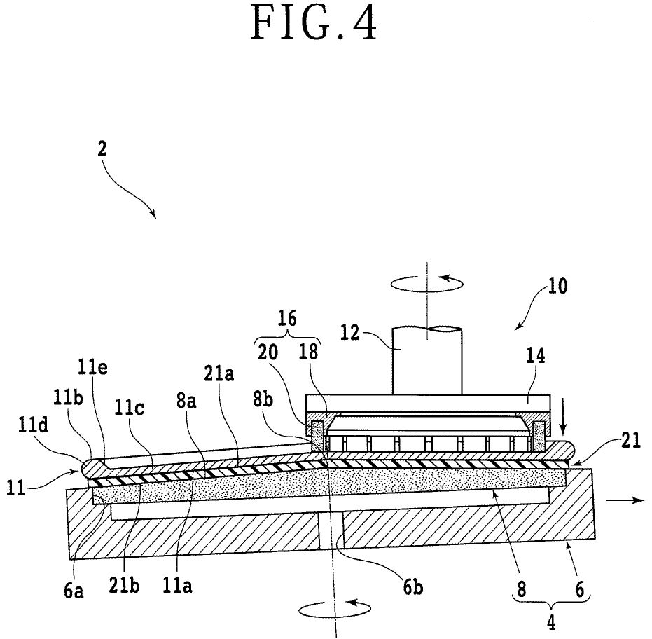

After the workpiece 11 is held on the chuck table 4, the portion of the workpiece 11 that corresponds to the area (device area) in which the devices 15 are formed is coarsely ground from the reverse side 11b (first grinding step). FIG. 3 is a cross sectional view schematically illustrating a state in which grinding of the workpiece 11 is started, and FIG. 4 is a cross sectional view schematically illustrating a state in which grinding of the workpiece 11 is proceeding. Note that FIGS. 3 and 4 depict side surfaces of some components for the convenience of description.

As illustrated in FIGS. 3 and 4, a first grinding unit (coarse grinding unit) 10 is disposed at a position above the chuck table 4 of the grinding apparatus 2. The first grinding unit 10 includes, for example, a tubular spindle housing (not illustrated). In a space inside the spindle housing, a columnar spindle 12 is housed.

On a lower end portion of the spindle 12, there is provided, for example, a circular plate-shaped mount 14 that has a smaller diameter than the workpiece 11. To a lower surface of the mount 14, a ring-shaped first grinding wheel (coarse grinding wheel) 16 that has substantially the same diameter as the mount 14 is fixed by a bolt (not illustrated) or the like.

The first grinding wheel 16 includes a ring-shaped wheel base 18 formed with use of such metal as stainless steel or aluminum. To a ring-shaped lower surface of the wheel base 18, there are fixed a plurality of first grindstones (coarse grindstones) 20 along a circumferential direction of the wheel base 18. Specifically, the plurality of first grindstones 20 are arrayed in an annular area that has a diameter (first diameter) smaller than that of the workpiece 11. Each of the first grindstones 20 has, for example, a structure in which relatively large abrasive grains including diamonds or the like are dispersed in a bonding agent composed of resin or the like.

Accordingly, when the workpiece 11 is ground by the first grinding wheel 16 including the first grindstones 20, the amount of the workpiece 11 that can be removed per unit time increases, but a damaged layer including scratches or distortions is more likely to be formed on the ground side of the workpiece 11. To an upper end side of the spindle 12, a rotary drive source (not illustrated), such as a motor, is coupled. By power generated by the rotary drive source, the first grinding wheel 16 rotates about an axis along or slightly inclined with respect to the vertical direction.

Near or inside the first grinding wheel 16, there is provided a nozzle (not illustrated) configured to be capable of supplying grinding liquid (typically, water) to the first grindstones 20 and the like. The spindle housing is, for example, supported by a first grinding unit moving mechanism (not illustrated) of a ball screw type, and the first grinding unit 10 moves in the vertical direction by power generated by the first grinding unit moving mechanism.

When the workpiece 11 is to be ground by the first grinding unit 10 (first grinding wheel 16), first, the chuck table moving mechanism moves the chuck table 4 to a position directly below the first grinding unit 10. More specifically, the chuck table moving mechanism moves the chuck table 4 in the horizontal direction such that the first grinding wheel 16 (all the first grindstones 20) is disposed directly above the area in which the devices 15 are formed.

Then, as illustrated in FIG. 3, while the rotary drive source coupled to the frame body 6 and the rotary drive source coupled to the spindle 12 rotate the chuck table 4 and the first grinding wheel 16, respectively, the first grinding unit moving mechanism lowers the first grinding unit 10 (first grinding wheel 16). As a result, as illustrated in FIG. 3, the first grindstones 20 come into contact with the workpiece 11 from the reverse side 11b and start grinding the workpiece 11. Note that liquid is supplied from the nozzle to the workpiece 11, the first grindstones 20, and the like.

Further, in the present embodiment, as illustrated in FIG. 3, while the grinding of the workpiece 11 is performed by the first grinding wheel 16, the chuck table moving mechanism moves the chuck table 4 in the horizontal direction in such a manner that the center of rotation of the workpiece 11 and the center of rotation of the first grinding wheel 16 approach each other. Specifically, the first grinding wheel 16 and the workpiece 11 move relative to each other in a direction inclined with respect to the reverse side 11b, in such a manner that the center of rotation of the first grinding wheel 16 approaches the center of rotation of the workpiece 11 (in such a manner that a distance between the center of rotation of the workpiece 11 and the center of rotation of the first grinding wheel 16 decreases in the horizontal direction).

When grinding of the workpiece 11 proceeds by the above-mentioned operation, as illustrated in FIG. 4, the portion of the workpiece 11 with which the first grindstones 20 have come into contact becomes thin while the remaining portion of the workpiece 11 maintains to be thick. That is, the portion of the workpiece 11 that corresponds to the area in which the devices 15 are formed becomes thin and constitutes a circular plate-shaped first thin plate portion 11c. Further, the portion of the workpiece 11 that corresponds to an area (outer peripheral area) surrounding the area in which the devices 15 are formed maintains to be thick and constitutes an annular first thick plate portion 11d that surrounds the first thin plate portion 11c.

As described above, in the present embodiment, the first grinding wheel 16 and the workpiece 11 move relative to each other in a direction inclined with respect to the reverse side 11b. Thus, as illustrated in FIG. 4, an inverted circular truncated cone shape area on the reverse side 11b of the workpiece 11 is ground by the first grinding wheel 16. That is, an inner side surface 11e of the first thick plate portion 11d is inclined with respect to the reverse side 11b.

Note that there are no substantial limitations on the specific grinding conditions. For example, in order to realize efficient grinding of the workpiece 11, the rotational speed of the chuck table 4 is set to fall within the range of 100 rpm to 600 rpm, typically to 300 rpm, and the rotational speed of the first grinding wheel 16 is set to fall within the range of 1,000 rpm to 7,000 rpm, typically to 4,500 rpm.

Further, the lowering speed (grinding feed speed) of the first grinding unit 10 in a state in which the first grindstones 20 are in contact with the workpiece 11 is set to fall within the range of 0.8 μm/s to 10.0 μm/s, typically to 6.0 μm/s, and the distance of relative movement of the first grinding wheel 16 and the workpiece 11 in the horizontal direction during the period from the time when the first grindstones 20 come into contact with the workpiece 11 to the time when the grinding of the workpiece 11 ends is set to fall within the range of 50 μm to 1,000 μm, typically to 400 μm.

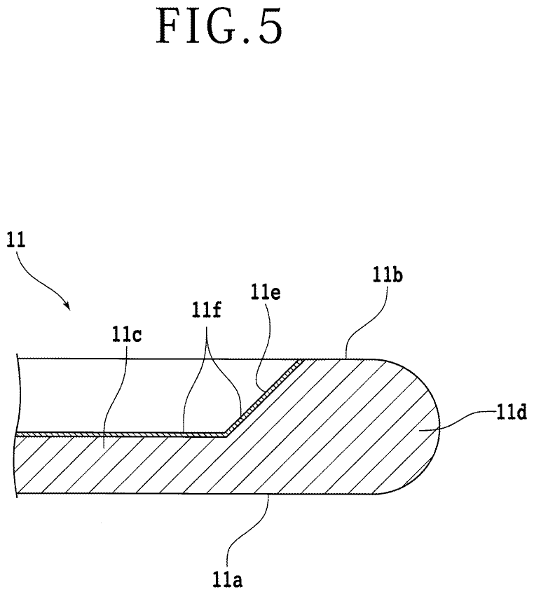

FIG. 5 is a cross sectional view schematically illustrating part of the workpiece 11 that has been ground by the first grinding wheel 16. As illustrated in FIG. 5, a portion (ground side) of the first thin plate portion 11c on the reverse side 11b that has been ground by the first grindstones 20 including relatively large abrasive grains has a damaged layer 11f including scratches or distortions. The damaged layer 11f lowers the mechanical strength (die strength or the like) of the workpiece 11, so that the area in which the damaged layer 11f is present cannot be used for products.

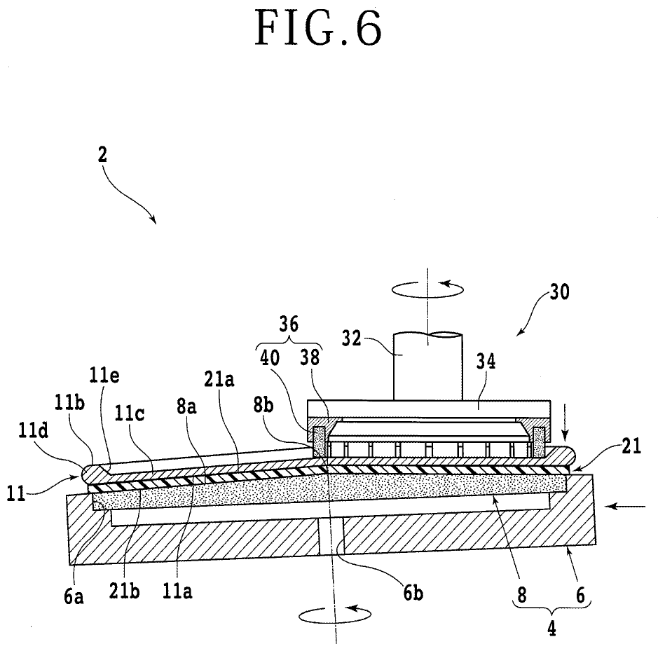

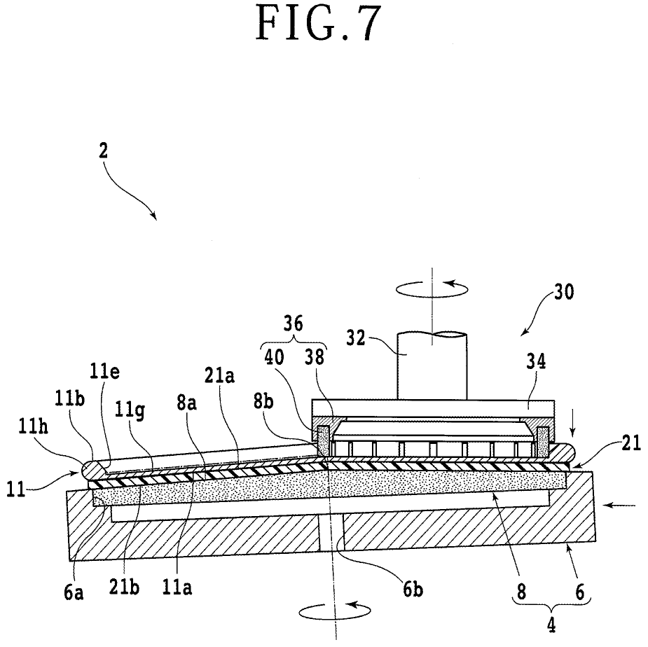

As such, after grinding is performed by the first grinding wheel 16, the first thin plate portion 11c and the first thick plate portion 11d are ground with higher accuracy from the reverse side 11b such that the damaged layer 11f is removed (second grinding step). FIG. 6 is a cross sectional view schematically illustrating a state in which grinding of the workpiece 11 is started, and FIG. 7 is a cross sectional view schematically illustrating a state in which grinding of the workpiece 11 is proceeding. Note that FIGS. 6 and 7 depict side surfaces of some components for the convenience of description.

As illustrated in FIGS. 6 and 7, a second grinding unit (finish grinding unit) 30 different from the first grinding unit 10 is disposed at a position above the chuck table 4 of the grinding apparatus 2. The second grinding unit 30 includes, for example, a tubular spindle housing (not illustrated). In a space inside the spindle housing, a columnar spindle 32 is housed.

On a lower end portion of the spindle 32, there is provided, for example, a circular plate-shaped mount 34 that has a smaller diameter than the workpiece 11. To a lower surface of the mount 34, a ring-shaped second grinding wheel (finish grinding wheel) 36 that has substantially the same diameter as the mount 34 is fixed by a bolt (not illustrated) or the like.

The second grinding wheel 36 includes a ring-shaped wheel base 38 formed with use of such metal as stainless steel or aluminum. To a ring-shaped lower surface of the wheel base 38, there is fixed a plurality of second grindstones (finish grindstones) 40 along a circumferential direction of the wheel base 38. Specifically, the plurality of second grindstones 40 are arrayed in an annular area that has a diameter (second diameter) smaller than that of the workpiece 11.

Each of the second grindstones 40 has, for example, a structure in which relatively small abrasive grains including diamonds or the like are dispersed in a bonding agent composed of resin or the like. That is, the second grindstones 40 include smaller abrasive grains than the first grindstones 20. Typically, the size (for example, the average grain size) of the abrasive grains included in the second grindstones 40 is smaller than the size (for example, the average grain size) of the abrasive grains included in the first grindstones 20. Note that, in the present specification, the grain size (median diameter; d50 diameter; 50% diameter) at a cumulative value of 50% in a grain size distribution measured by the laser diffraction/scattering method is treated as the average grain size.

When the workpiece 11 is ground by the second grinding wheel 36 including the second grindstones the amount of the workpiece 11 that can be removed per unit time becomes small compared to that in the case in which the workpiece 11 is ground by the first grinding wheel 16, but the damaged layer 11f is less likely to be generated. To an upper end side of the spindle 32, a rotary drive source (not illustrated), such as a motor, is coupled. By power generated the rotary drive source, the second grinding wheel 36 rotates about an axis along or slightly inclined with respect to the vertical direction.

Near or inside the second grinding wheel 36, there is provided a nozzle (not illustrated) configured to be capable of supplying grinding liquid (typically, water) to the second grindstones 40 and the like. The spindle housing is, for example, supported by a second grinding unit moving mechanism (not illustrated) of a ball screw type, and the second grinding unit 30 moves in the vertical direction by power generated by the second grinding unit moving mechanism.

When the workpiece 11 is to be ground by the second grinding unit 30 (second grinding wheel 36), first, the chuck table moving mechanism moves the chuck table 4 to a position directly below the second grinding unit 30. More specifically, the chuck table moving mechanism moves the chuck table 4 in the horizontal direction in such a manner that the second grinding wheel 36 (all of the second grindstones 40) is disposed directly above the first thin plate portion 11c.

Then, as illustrated in FIG. 6, while the rotary drive source coupled to the frame body 6 and the rotary drive source coupled to the spindle 32 rotate the chuck table 4 and the second grinding wheel 36, respectively, the second grinding unit moving mechanism lowers the second grinding unit 30 (second grinding wheel 36). As a result, as illustrated in FIG. 6, the second grindstones 40 come into contact with the workpiece 11 (first thin plate portion 11c) from the reverse side 11b, and start grinding the workpiece 11. Note that liquid is supplied from the nozzle to the workpiece 11, the second grindstones 40, and the like.

Further, in the present embodiment, as illustrated in FIG. 6, while the grinding of the workpiece 11 is performed by the second grinding wheel 36, the chuck table moving mechanism moves the chuck table 4 in the horizontal direction such that the center of rotation of the workpiece 11 and the center of rotation of the second grinding wheel 36 are distanced from each other. In other words, the second grinding wheel 36 and the workpiece 11 move relative to each other in a direction inclined with respect to the reverse side 11b, in such a manner that the center of rotation of the second grinding wheel 36 is distanced from the center of rotation of the workpiece 11 (in such a manner that the distance between the center of rotation of the workpiece 11 and the center of rotation of the second grinding wheel 36 increases in the horizontal direction).

When grinding of the workpiece 11 proceeds by the above-mentioned operation, the second grindstones 40 first come into contact with the first thin plate portion 11c from the reverse side 11b and then come into contact with the inclined side surface 11e of the first thick plate portion 11d. As a result, as illustrated in FIG. 7, the first thin plate portion 11c is ground by the lower surface of the second grindstones 40, and the damaged layer 11f of the first thin plate portion 11c is removed. Moreover, the inner side of the first thick plate portion 11d is ground by an outer side surface of the second grindstones 40, so that the inclined side surface 11e of the first thick plate portion 11d is partially removed together with the damaged layer 11f.

Note that there are no substantial limitations on the specific grinding conditions. For example, in order to realize efficient and highly accurate grinding of the workpiece 11, the rotational speed of the chuck table 4 is set to fall within the range of 100 rpm to 600 rpm, typically to 300 rpm, and the rotational speed of the second grinding wheel 36 is set to fall within the range of 1,000 rpm to 7,000 rpm, typically to 4,000 rpm.

Further, the lowering speed (grinding feed speed) of the second grinding unit 30 in a state in which the second grindstones 40 are in contact with the workpiece 11 is set to fall within the range of 0.1 μm/s to 0.8 μm/s, typically to 0.6 μm/s, and the distance of relative movement of the second grinding wheel 36 and the workpiece 11 in the horizontal direction during the period from the time when the second grindstones 40 come into contact with the workpiece 11 to the time when the grinding of the workpiece 11 ends is set to fall within the range of 50 μm to 1,000 μm, typically to 300 μm.

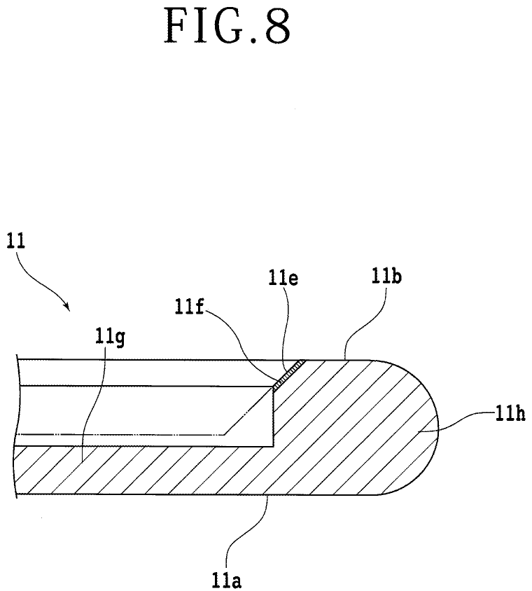

FIG. 8 is a cross sectional view schematically illustrating part of the workpiece 11 that has been ground by the second grinding wheel 36. As illustrated in FIG. 8, the first thin plate portion 11c that has been ground and a portion of the first thick plate portion 11d from which the side surface 11e has been removed constitute a circular plate-shaped second thin plate portion 11g, while the remaining portion of the first thick plate portion 11d constitutes an annular second thick plate portion 11h that surrounds the second thin plate portion 11g. That is, the second thin plate portion 11g is larger in diameter but thinner than the first thin plate portion 11c.

As described above, in the workpiece grinding method according to the present embodiment, first, the workpiece 11 is ground by the first grinding wheel 16 that includes the first grindstones 20, to form the first thin plate portion 11c and the annular first thick plate portion 11d which has the inclined inner side surface 11e. Next, the second grindstones 40 that include small abrasive grains compared to the first grindstones 20 and that are included in the second grinding wheel 36 are caused to come into contact with the first thin plate portion 11c and then with the inclined side surface 11e of the first thick plate portion 11d, to grind the workpiece 11 in such a manner that part of the side surface 11e of the first thick plate portion 11d is partially removed, so that the second thin plate portion 11g and the second thick plate portion 11h are formed.

Accordingly, the second thin plate portion 11g in whole becomes an effective area free of any damaged layer 11f attributable to the first grindstones 20. Further, at this time, the first thick plate portion 11d is ground in such a manner that part of the inclined side surface 11e is partially removed, so that the first thick plate portion 11d is less likely to chip, unlike in a case in which the second grindstones 40 are caused to come into contact with a perpendicular side surface to grind the first thick plate portion 11d from the lateral side.

Further, since the volume of portion of the first thick plate portion 11d that is removed by the second grinding wheel 36 is sufficiently small, for example, the length of time required for grinding does not become considerably long compared to the length of time required in the grinding method in the related art in which the second grinding wheel 36 grinds only the area on the central side of the first thin plate portion 11c and not the first thick plate portion 11d at all. Accordingly, the workpiece grinding method according to the present embodiment sufficiently reserves an effective area that can be used for products, without requiring a considerably longer time than the grinding method in the related art.

Note that, although part of the inclined side surface 11e and the damaged layer 11f remain in the second thick plate portion 11h, the area in which the damaged layer 11f is present is sufficiently distanced from the second thin plate portion 11g along the thickness direction of the workpiece 11. Thus, the damaged layer 11f does not adversely affect the devices 15 formed in the second thin plate portion 11g.

Note that the present invention can be modified and implemented in various manners without being limited by the description made in the above-mentioned embodiment. For example, in the embodiment, the workpiece 11 is ground by the first grinding unit 10 and the second grinding unit 30 being lowered and the chuck table 4 being moved in the horizontal direction. However, the manner of moving each unit is not limited to the above-mentioned form.

For example, the workpiece 11 may be ground by the first grinding unit 10 and the second grinding unit 30 being moved in the horizontal direction and the chuck table 4 being raised. Alternatively, the workpiece 11 may be ground by the first grinding unit 10 and the second grinding unit 30 being lowered and moved in the horizontal direction. Similarly, the workpiece 11 may be ground by the chuck table 4 being moved in the horizontal direction and raised.

Further, in the embodiment, the second grinding wheel 36 and the workpiece 11 are moved relative to each other in a direction inclined with respect to the reverse side 11b, in such a manner that the center of rotation of the second grinding wheel 36 is distanced from the center of rotation of the workpiece 11. Yet, the manner of moving the second grinding wheel 36 and the workpiece 11 relative to each other is not limited to the above-mentioned form.

Under the condition that the part of the side surface 11e of the first thick plate portion 11d is partially removed by the second grindstones 40 being caused to come into contact with one of the first thin plate portion 11c or the part of the side surface 11e of the first thick plate portion 11d from the reverse side 11b and then with the other of the first thin plate portion 11c or the part of the side surface 11e of the first thick plate portion 11d, the manner of moving the second grinding wheel 36 and the workpiece 11 relative to each other can freely be modified.

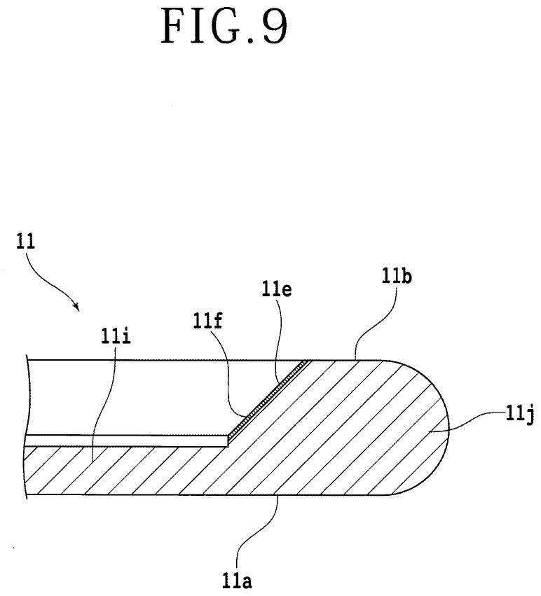

FIG. 9 is a cross sectional view schematically illustrating part of the workpiece 11 that is being ground by the second grinding wheel 36 in the workpiece grinding method according to a first modification of the embodiment. In the workpiece grinding method according to the first modification, for example, the second grinding wheel 36 and the workpiece 11 are moved relative to each other in a direction that intersects the reverse side 11b, in such a manner that the center of rotation of the second grinding wheel 36 is not distanced from the center of rotation of the workpiece 11 (in such a manner that the distance between the center of rotation of the workpiece 11 and the center of rotation of the second grinding wheel 36 does not increase in the horizontal direction), so that at least the first thin plate portion 11c is ground. Typically, the second grinding wheel 36 and the workpiece 11 are moved relative to each other in a direction perpendicular to the reverse side 11b.

As a result, a circular plate-shaped intermediate thin plate portion 11i that is thinner than the first thin plate portion 11c and an annular intermediate thick plate portion 11j that surrounds the intermediate thin plate portion 11i are obtained, as illustrated in FIG. 9. Note that the diameter of the intermediate thin plate portion 11i is equal to or smaller than the diameter of the first thin plate portion 11c. That is, at this stage, a portion of the first thin plate portion 11c that is adjacent to the first thick plate portion 11d sometimes remains unground. In that case, the unground portion of the first thin plate portion 11c and the first thick plate portion 11d constitute the intermediate thick plate portion 11j.

After the intermediate thin plate portion 11i with the damaged layer 11f being removed is formed, the second grinding wheel 36 and the workpiece 11 are moved relative to each other in a direction along the reverse side 11b in such a manner that the center of rotation of the second grinding wheel 36 is distanced from the center of rotation of the workpiece 11 (in such a manner that the distance between the center of rotation of the workpiece 11 and the center of rotation of the second grinding wheel 36 increases in the horizontal direction), so that at least the side surface 11e remaining in the intermediate thick plate portion 11j (the side surface 11e of the first thick plate portion 11d) is partially removed.

As a result, the circular plate-shaped second thin plate portion 11g and the annular second thick plate portion 11h that surrounds the second thin plate portion 11g are obtained, as illustrated in FIG. 8. Note that, other portions of the workpiece grinding method according to the first modification (portions except the grinding performed by the second grinding wheel 36) may be the same as those in the workpiece grinding method according to the embodiment.

Further, instead of being moved in the manner described above, the second grinding wheel 36 and the workpiece 11 may first be moved relative to each other in a direction along the reverse side 11b in such a manner that the center of rotation of the second grinding wheel 36 is distanced from the center of rotation of the workpiece 11 (in such a manner that the distance between the center of rotation of the workpiece 11 and the center of rotation of the second grinding wheel 36 increases in the horizontal direction), so that at least the side surface 11e of the first thick plate portion 11d is partially removed, and the second grinding wheel 36 and the workpiece 11 may then be moved relative to each other in a direction that intersects the reverse side 11b, in such a manner that the center of rotation of the second grinding wheel 36 is not distanced from the center of rotation of the workpiece 11 (in such a manner that the distance between the center of rotation of the workpiece 11 and the center of rotation of the second grinding wheel 36 does not increase in the horizontal direction), so that at least the first thin plate portion 11c is removed.

Also in this case, ultimately, the circular plate-shaped second thin plate portion 11g and the annular second thick plate portion 11h that surrounds the second thin plate portion 11g are obtained, as illustrated in FIG. 8. Other portions of the workpiece grinding method (portions except the grinding performed by the second grinding wheel 36) may be the same as those in the above-mentioned embodiment.

Further, in the embodiment described above, the first grinding wheel 16 and the workpiece 11 are moved relative to each other in a direction inclined with respect to the reverse side 11b, in such a manner that the center of rotation of the first grinding wheel 16 approaches the center of rotation of the workpiece 11. Yet, the manner of moving the first grinding wheel 16 and the workpiece 11 relative to each other is not limited to the above-mentioned form. Under the condition that a circular plate-shaped first thin plate portion and an annular first thick plate portion that surrounds the first thin plate portion and that has an inner side surface at least part of which is inclined with respect to the reverse side 11b are obtained, the manner of moving the first grinding wheel 16 and the workpiece 11 relative to each other can freely be modified.

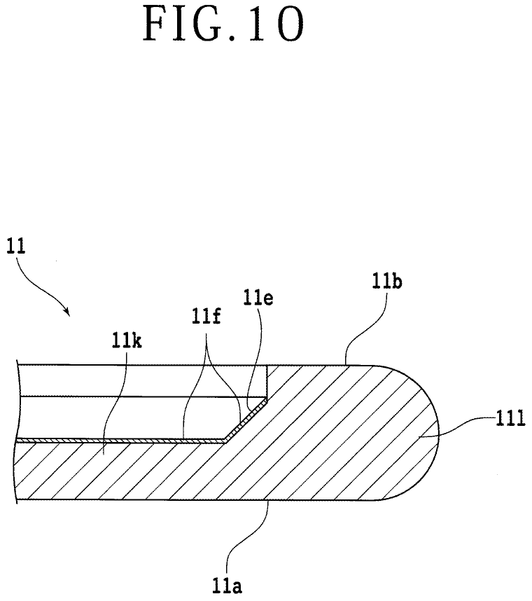

FIG. 10 is a cross sectional view schematically illustrating part of the workpiece 11 that has been ground by the first grinding wheel 16 in the workpiece grinding method according to a second modification of the embodiment. In the workpiece grinding method according to the second modification, the first grinding wheel 16 and the workpiece 11 are moved relative to each other in a direction that intersects the reverse side 11b, in such a manner that the center of rotation of the first grinding wheel 16 does not approach the center of rotation of the workpiece 11 (in such a manner that the distance between the center of rotation of the workpiece 11 and the center of rotation of the first grinding wheel 16 does not decrease in the horizontal direction). Typically, the first grinding wheel 16 and the workpiece 11 are moved relative to each other in a direction perpendicular to the reverse side 11b.

Thereafter, the first grinding wheel 16 and the workpiece 11 are moved relative to each other in a direction inclined with respect to the reverse side 11b, in such a manner that the center of rotation of the first grinding wheel 16 approaches the center of rotation of the workpiece 11 (in such a manner that the distance between the center of rotation of the workpiece 11 and the center of rotation of the first grinding wheel 16 decreases in the horizontal direction). As a result, a circular plate-shaped first thin plate portion 11k and an annular first thick plate portion 11l that surrounds the first thin plate portion 11k are obtained, as illustrated in FIG. 10.

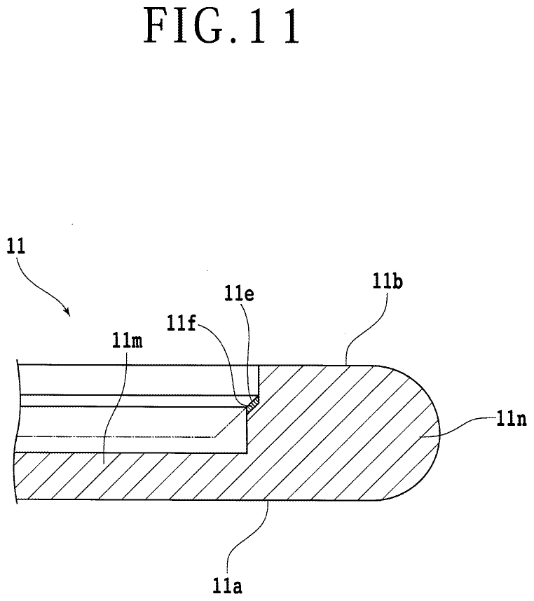

In the second modification, as in the embodiment and the first modification, for example, the second grinding wheel 36 is next used to remove the damaged layer 11f of the workpiece 11. FIG. 11 is a cross sectional view schematically illustrating part of the workpiece 11 that has been ground by the second grinding wheel 36 in the workpiece grinding method according to the second modification.

In this case, ultimately, a circular plate-shaped second thin plate portion 11m that is larger in diameter but thinner than the first thin plate portion 11k and an annular second thick plate portion 11n that surrounds the second thin plate portion 11m are obtained, as illustrated in FIG. 11. Other portions of the workpiece grinding method according to the second modification (portions except the grinding performed by the first grinding wheel 16) may be the same as those in the embodiment and the first modification, for example,

Further, in the embodiment and the modifications, the workpiece 11 may be ground by a grinding apparatus including a chuck table that holds the workpiece 11 when the workpiece 11 is to be ground by the first grinding wheel 16 and another chuck table that holds the workpiece 11 when the workpiece 11 is to be ground by the second grinding wheel 36. Similarly, the workpiece 11 may be ground by a grinding apparatus including the first grinding unit 10 and another grinding apparatus including the second grinding unit 30.

In addition, structures, methods, and the like according to the embodiment and the modifications can appropriately be modified and implemented within the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A workpiece grinding method that is applied when a circular plate-shaped workpiece having a first surface and a second surface on an opposite side of the first surface is to be ground, the workpiece grinding method comprising:
a first grinding step of grinding the workpiece by moving the workpiece and a first grinding wheel relative to each other while rotating them, the first grinding wheel including a plurality of first grindstones that each include abrasive grains and are arrayed in an annular area with a first diameter smaller than a diameter of the workpiece, and causing the first grindstones to come into contact with the workpiece from the second surface side, to thereby form in the workpiece a circular plate-shaped first thin plate portion and an annular first thick plate portion that surrounds the first thin plate portion and that has an inner side surface at least part of which is inclined with respect to the second surface; and
a second grinding step of, after the first grinding step, grinding the workpiece by moving the workpiece and a second grinding wheel relative to each other while rotating them, the second grinding wheel including a plurality of second grindstones that each include abrasive grains smaller than those of the first grindstones and are arrayed in an annular area with a second diameter smaller than the diameter of the workpiece, and causing the second grindstones to come into contact with one of the first thin plate portion or the part of the side surface of the first thick plate portion from the second surface side and then with the other of the first thin plate portion or the part of the side surface of the first thick plate portion, in such a manner that the part of the side surface of the first thick plate portion is partially removed, to thereby form in the workpiece a circular plate-shaped second thin plate portion that is larger in diameter but thinner than the first thin plate portion and an annular second thick plate portion that surrounds the second thin plate portion.

2. The workpiece grinding method according to claim 1, wherein,
in the first grinding step, the first grinding wheel and the workpiece are moved relative to each other in a direction inclined with respect to the second surface, in such a manner that a center of rotation of the first grinding wheel approaches a center of rotation of the workpiece.

3. The workpiece grinding method according to claim 1, wherein,
in the first grinding step, after the first grinding wheel and the workpiece are moved relative to each other in a direction that intersects the second surface, in such a manner that a center of rotation of the first grinding wheel does not approach a center of rotation of the workpiece, the first grinding wheel and the workpiece are moved relative to each other in a direction inclined with respect to the second surface, in such a manner that the center of rotation of the first grinding wheel approaches the center of rotation of the workpiece.

4. The workpiece grinding method according to claim 1, wherein,
in the second grinding step, the second grinding wheel and the workpiece are moved relative to each other in a direction inclined with respect to the second surface, in such a manner that a center of rotation of the second grinding wheel is distanced from a center of rotation of the workpiece.

5. The workpiece grinding method according to claim 1, wherein,
in the second grinding step, after at least the first thin plate portion is ground by moving the second grinding wheel and the workpiece relative to each other in a direction that intersects the second surface, in such a manner that a center of rotation of the second grinding wheel is not distanced from a center of rotation of the workpiece, at least the part of the side surface of the first thick plate portion is partially removed by moving the second grinding wheel and the workpiece relative to each other in a direction along the second surface in such a manner that the center of rotation of the second grinding wheel is distanced from the center of rotation of the workpiece.

6. The workpiece grinding method according to claim 1, wherein,
in the second grinding step, after at least the part of the side surface of the first thick plate portion is partially removed by moving the second grinding wheel and the workpiece relative to each other in a direction along the second surface in such a manner that a center of rotation of the second grinding wheel is distanced from a center of rotation of the workpiece, at least the first thin plate portion is ground by moving the second grinding wheel and the workpiece relative to each other in a direction that intersects the second surface, in such a manner that the center of rotation of the second grinding wheel is not distanced from the center of rotation of the workpiece.
